(19) United States
(12) Patent Application Publication
(10) Pub. No.: US 2016/0372529 A1
(43) Pub. Date: Dec. 22, 2016

(54) PACKAGING METHOD, DISPLAY PANEL AND METHOD FOR MANUFACTURING THE SAME, AND DISPLAY DEVICE

(71) Applicants: BOE TECHNOLOGY GROUP CO., LTD., Beijing (CN); ORDOS YUANSHENG OPTOELECTRONICS CO., LTD., Dongsheng District, Ordos (CN)

(72) Inventors: Haidong WU, Beijing (CN); Taegyu KIM, Beijing (CN); Qun MA, Beijing (CN)

(73) Assignees: ORDOS YUANSHENG OPTOELECTRONICS CO., LTD., Dongsheng District, Ordos (CN); BOE TECHNOLOGY GROUP CO., LTD., Beijing (CN)

(21) Appl. No.: 14/770,918

(22) PCT Filed: Dec. 3, 2014
(86) PCT No.: PCT/CN2014/092941

§ 371 Date: Aug. 27, 2015

(30) Foreign Application Priority Data
Jan. 9, 2014 (CN) 201410441251.3

(51) Int. Cl. H01L 27/32; H01L 51/52; H01L 51/56

(52) U.S. Cl. CPC H01L 27/3251; H01L 51/56; H01L 51/5246

(57) ABSTRACT

The present invention discloses a method for packaging a display panel, a display panel and a method for manufacturing the same, and a display device. The display panel comprises a first substrate and a second substrate, wherein the first substrate comprises a first packaging region, the second substrate comprises a second packaging region, and a position of the first packaging region corresponds to that of the second packaging region. The method comprises: step A, roughening a surface of at least one of a first packaging region and a second packaging region, and forming a non-smooth surface; step B, coating a sealant on the surface of the first packaging region and/or the second packaging region that is treated in step A; step C, oppositely arranging the first substrate and the second substrate, which are treated in step B, to form a cell; and step D, curing the sealant.

### CROSS REFERENCE TO RELATED APPLICATION

The present application claims priority of the Chinese application No. 201410441251.3 filed in China on Sep. 1, 2014, the entire contents of which is incorporated by reference.

### FIELD OF THE INVENTION

The present invention relates to a field of packaging technologies, and in particular, to a packaging method, a display panel and a method for manufacturing the same, and a display device.

### DESCRIPTION OF THE PRIOR ART

Due to the advantages of high brightness, wide visual angle, active luminescence, high contrast, ultrathinness and portability, etc., Organic Light-Emitting Diode (OLED, for short) display apparatus has become a novel flat-panel display apparatus with the greatest development prospect.

An OLED includes a metal anode, a hole transport layer, an organic luminescent layer, an electron transport layer and a metal cathode that are formed between two substrates that are oppositely arranged to form a cell, the four sides of the two substrates that are oppositely arranged to form a cell are sealed via a sealant, and the metal anode and the metal cathode act jointly to drive the organic luminescent layer to emit light.

However, LED display apparatus also has some technical bottlenecks, one of which is a problem of the lifetime of an OLED display apparatus. Because the organic luminescent layer of an OLED is very sensitive to a pollutant, oxygen and water vapor in the atmosphere, and at the same time, the water vapor in the atmosphere may electrochemically corrode the metal electrode, the lifetime of the OLED display apparatus will be seriously affected. Therefore, the packaging technology of an OLED display apparatus becomes a key process for improving the lifetime of the OLED display apparatus, and it becomes an urgent task to research and develop an effective packaging technology for blocking H₂O and O₂.

### SUMMARY OF THE INVENTION

The present invention provides a packaging method, a display panel and a method for manufacturing the same, and a display device, which can guarantee that a display panel has a good sealability.

In order to solve the above technical problems, the invention provides a method for packaging a display panel, wherein the display panel includes a first substrate and a second substrate, the first substrate includes a first packaging region, the second substrate includes a second packaging region, and the position of the first packaging region corresponds to the position of the second packaging region, and the method includes:

step A: roughening a surface of at least one of the first packaging region and the second packaging region, and forming a non-smooth surface;

step B: coating a sealant on the surface of the first packaging region and/or the second packaging region that is treated in step A;

step C: oppositely arranging the first substrate and the second substrate, which are treated in step B, to form a cell; and

step D: curing the sealant.

Optionally, in step A, the surface of the at least one of the first packaging region and the second packaging region is roughened by a chemical corrodent.

Optionally, the chemical corrodent is a mixed liquor of H₂O₂ with a mol concentration of about 20% to about 40% and H₂SO₄ with a mol concentration of about 60% to about 80%, a mixed liquor of HF with a mol concentration of about 40% to about 60% and H₂SO₄ with a mol concentration of about 40% to about 60%, or a mixed liquor of HNO₃ with a mol concentration of about 65% to about 85% and HCl with a mol concentration of about 15% to about 35%. Optionally, the chemical corrodent is coated on a surface of the at least one of the first packaging region and the second packaging region by spray coating.

Optionally, the precision of the spray coating is about 20 μm.

Optionally, the non-smooth surface has a uniform and continuous geometric shape.

Optionally, after step A and before step B, the method further includes:

step E: removing the chemical corrodent.

Optionally, the chemical corrodent is removed by washing with water.

Optionally, after removing the chemical corrodent, the method further includes: performing heat treatment at a temperature of about 80° C. to about 100V.

Optionally, the time of the heat treatment is from about 20 min to about 30 min.

Optionally, the sealant is glass cement, and the step of curing the sealant includes irradiating the glass cement by a laser to fuse and then cure the glass cement.

Optionally, the sealant is a seal agent, and the step of curing the sealant includes irradiating the seal agent by ultraviolet light to cure the seal agent.

The invention further provides a method for manufacturing a display panel, wherein the display panel includes a first substrate and a second substrate, the first substrate includes a first packaging region, the second substrate includes a second packaging region, and the position of the first packaging region corresponds to the position of the second packaging region, and the method includes: packaging the first substrate and the second substrate by the above-described method.

The invention further provides a display panel, which includes:

a first substrate and a second substrate, wherein the first substrate includes a first packaging region, the second substrate includes a second packaging region, and the position of the first packaging region corresponds to the position of the second packaging region; and

a sealant cured between the first substrate and the second substrate, wherein:

a surface of at least one of the first packaging region and the second packaging region is a non-smooth surface, and the sealant is cured on the non-smooth surface.

Optionally, the sealant is glass cement or a seal agent.

Optionally, the display panel is an OLED display panel or a liquid crystal display panel.

The invention further provides a display device, which includes the above display panel.

The above technical solutions of the invention has the following beneficial effects:

In the above technical solutions, by roughening the surface of at least one packaging region of two substrates that are oppositely arranged to form a cell, a non-smooth surface is formed, and the contact area between the sealant and the substrate is increased, so that the adhesivity between the sealant formed in the packaging region and the substrate is enhanced, the performance of blocking water vapor and oxygen is improved greatly, and it guarantees that the display panel has a good sealability, thereby the lifetime of the display apparatus can be improved.

### BRIEF DESCRIPTION OF THE DRAWINGS

In order to more clearly illustrate the technical solutions of the embodiments of the invention or the prior art, the drawings required in the description of the embodiments or the prior art will be briefly introduced below. Apparently, the drawings in the description below only show some embodiments of the invention, and other drawings may also be obtained by one of ordinary skills in the art based on these drawings without creative work.

FIG. 1 shows a structural representation of a display panel according to one embodiment of the invention;

FIG. 2 shows a top view of a first substrate according to one embodiment of the invention;

FIG. 3a and FIG. 3b show partial schematic diagrams of a non-smooth surface formed after roughening the surface of the packaging region according to one embodiment of the invention;

FIG. 4 shows a structural representation of a first substrate of an OLED display panel according to one embodiment of the invention;

FIG. 5 shows a structural representation of a second substrate of an OLED display panel according to one embodiment of the invention;

FIG. 6 is schematic diagram 1 showing the curing of a sealant after oppositely arranging the first substrate and the second substrate to form a cell according to one embodiment of the invention;

FIG. 7 is schematic diagram 2 showing the curing of a sealant after oppositely arranging the first substrate and the second substrate to form a cell according to one embodiment of the invention;

FIG. 8 shows a flow chart of a method for packaging a display panel according to one embodiment of the invention; and

FIG. 9 shows a flow chart of a method for packaging a display panel according to another embodiment of the invention.

### DETAILED DESCRIPTION OF THE PREFERRED EMBODIMENTS

The invention provides a packaging method, which is adapted to oppositely package the two substrates of a display panel to form a cell. In the packaging method of the invention, by roughening the surface of at least one packaging region of two substrates that are oppositely arranged to form a cell, a non-smooth surface is formed, and the contact area between the sealant and the substrate is increased, so that the adhesivity between the sealant formed in the packaging region and the substrate is enhanced, the performance of blocking water vapor and oxygen is improved greatly, and it guarantees that the display panel has a good sealability, thereby the lifetime of the display apparatus can be improved.

The specific implementation modes of the invention will be further described in detail below in conjunction with the drawings and embodiments. The embodiments below are used for illustrating the invention, rather than limiting the scope of the invention.

In the embodiments of the invention, the technical solutions of the invention will be specifically described by an example in which the two substrates of a display panel are oppositely packaged to form a cell, However, the technical solutions of the invention will not be limited to display panels only.

One embodiment of the invention provides a method for packaging a display panel, wherein the display panel includes a first substrate and a second substrate. The first substrate includes a first packaging region, the second substrate includes a second packaging region, and the position of the first packaging region corresponds to the position of the second packaging region.

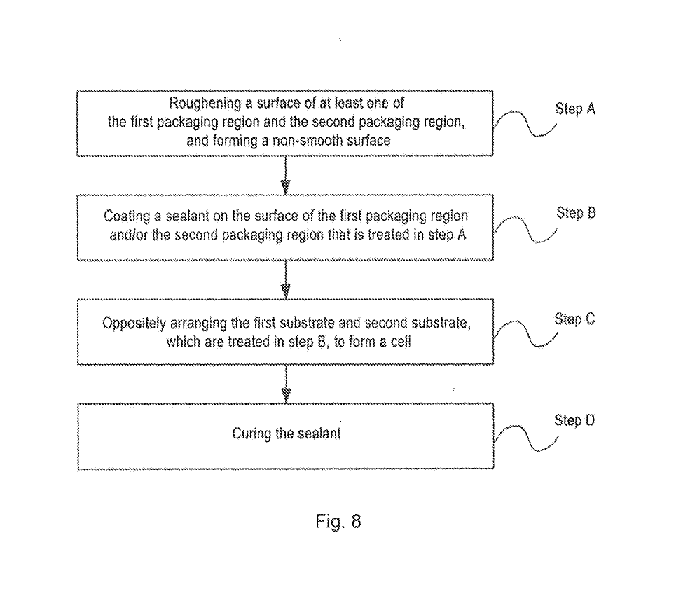

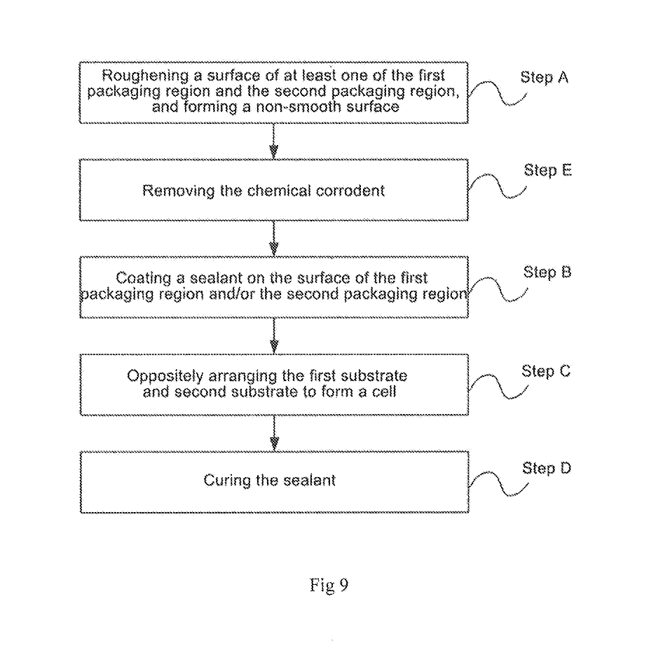

Referring to FIG. 8, the method includes:

step A: roughening a surface of at least one of the first packaging region and the second packaging region, and forming a non-smooth surface;

step B: coating a sealant on the surface of the first packaging region and/or the second packaging region that is treated in step A;

step C: oppositely arranging the first substrate and the second substrate, which are treated in step B, to form a cell; and

step D: curing the sealant.

By the above packaging method, the sealant is cured between the first packaging region with a non-smooth surface and the second packaging region, so that the adhesivity between the sealant and the substrate will be enhanced, the performance of blocking water vapor and oxygen will be improved greatly, and it may guarantee that the display panel has a good sealability, thereby the lifetime of the display apparatus will be prolonged.

Correspondingly, one embodiment of the invention further provides a display panel and a method for manufacturing the same, wherein the display panel includes a first substrate and a second substrate, the first substrate includes a first packaging region, the second substrate includes a second packaging region, and the position of the first packaging region corresponds to the position of the second packaging region. The manufacture method includes packaging the first substrate and the second substrate by the above packaging method, so that when the first packaging region and the second packaging region are oppositely arranged to form a cell, at least one of the opposite surfaces is a non-smooth surface, and the sealant is cured on the non-smooth surface, thus the adhesivity between the sealant and the substrate will be enhanced, the performance of blocking water vapor and oxygen will be improved greatly, and it may guarantee that the display panel has a good sealability.

The invention further provides a display device, which includes the above display panel. Since the display panel has a good sealability, the lifetime of the display device may be prolonged.

In the prior art, according to different display principles, display apparatuses may be divided into liquid crystal display apparatus and organic light-emitting diode (OLED) display apparatus, etc. OLED display apparatus has the advantages of high brightness, wide visual angle, active luminescence, high contrast, ultrathinness and portability, etc., and it has become a novel flat-panel display apparatus that is researched and developed in recent years. However, OLED display apparatus also has some technical bottlenecks, one of which is that the lifetime of the OLED display apparatus tends to be shortened due to the influence of ambient aqueous vapor and oxygen. Therefore, the packaging technology of an OLED display apparatus becomes a key process for improving the lifetime of the OLED display apparatus.

Since the packaging method of the invention can ensure a good sealability of an OLED display panel, when it is used for the packaging of an OLED display panel, the service life of the OLED display apparatus may be prolonged greatly.

Generally, a seal agent or glass cement is employed for packaging a display panel. When glass cement is used for packaging a display panel, the specific packaging process is as follows:

First of all, the surface of at least one of the first packaging region of the first substrate and the second packaging region of the second substrate is roughened to form a non-smooth surface;

Then, a liquid sealant is coated on the surface of the first packaging region and/or the second packaging region that has been treated as above, and the sealant is dried, wherein the liquid sealant is usually a mixture formed of glass frit and a solvent, the solvent functions to disperse the glass frit for easy coating, and the solvent will volatilize during the drying process;

Next, the first substrate and the second substrate that have been treated as above are oppositely arranged to form a cell, and the sealant located on the first substrate and the second substrate is irradiated by a laser to make it fuse;

Finally, the first substrate and the second substrate are pressed with an enough force to extrude the air, but no glass cement will not be extruded, and the first substrate and the second substrate that are spliced are placed at room temperature to wait for the glass cement to cure.

Up to this point, the packaging of the first substrate and the second substrate is completed.

When a seal agent is used for packaging a display panel, the specific packaging process is as follows:

First of all, the surface of at least one of the first packaging region of the first substrate and the second packaging region of the second substrate is roughened to form a non-smooth surface;

Next, a liquid seal agent is coated on the surface of the first packaging region and/or the second packaging region that has been treated as above;

Finally, the first substrate and the second substrate that have been treated as above are oppositely arranged to form a cell, and the seal agent is irradiated by ultraviolet light to make it cure.

Up to this point, the packaging of the first substrate and the second substrate is completed.

The seal agent may be ultraviolet curable glue.

Optionally, the surfaces of the first packaging region and the second packaging region of the two substrates of a display panel are both roughened to form a non-smooth surface, that is, the first packaging region has a non-smooth surface, and the second packaging region also has a non-smooth surface, and the sealant is cured on the non-smooth surface of the first substrate and the second substrate, so that the adhesivity between the sealant and the two substrates that are oppositely arranged to form a cell may be both enhanced, water vapor and oxygen may be better blocked, and it may ensure that the display panel has a good sealability.

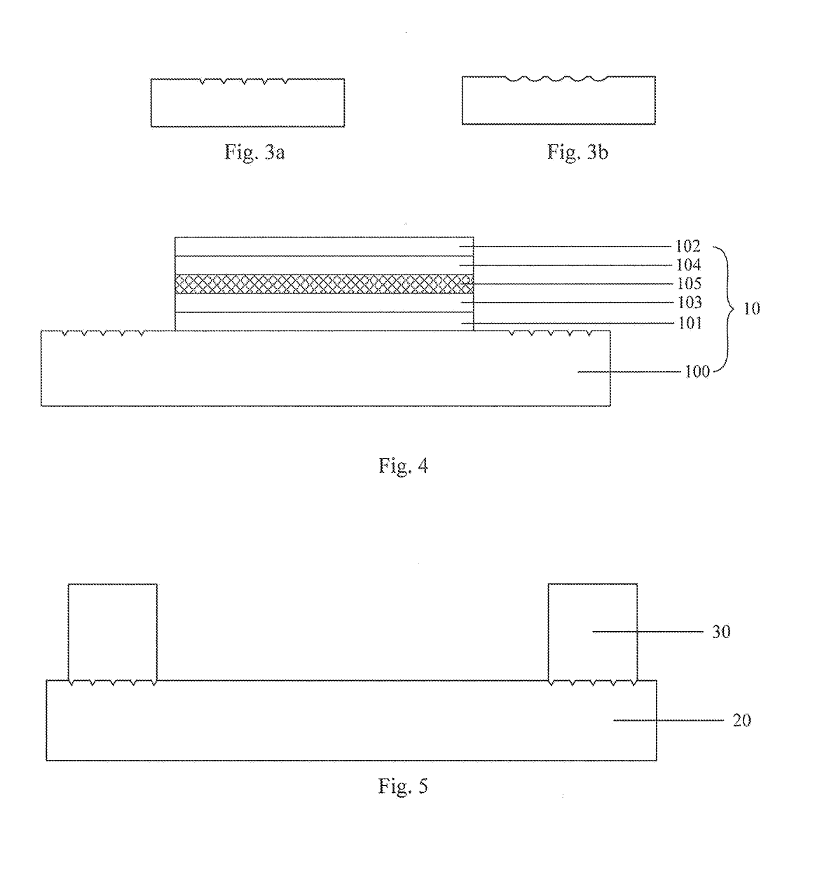

There exist many ways for roughening the surface of a substrate, which may be a physical method or a chemical method. For example, in one specific embodiment, the surfaces of the first packaging region and the second packaging region are roughened via a chemical corrodent, and the impact of a physical method may be avoided, thus the substrate will not be damaged. The chemical corrodent may be coated on the surface of at least one of the first packaging region and the second packaging region via spray coating, the precision of spray coating may reach ±20 μm, and the corrosion width may be controlled by the spray coating amount of a spray head. By this method, a rough surface with a continuous geometric shape as shown in FIGS. 3a and 3b may be formed via corrosion, so that the contact area between the sealant and the substrate may be increased, and the adhesivity between the sealant and the substrate may be further enhanced. Since the substrate material of a display panel is usually glass, quartz or an organic resin, a mixed liquor of H₂O₂ with a mol concentration of about 20% to about 40% and H₂SO₄ with a mol concentration of about 60% to about 80%, a mixed liquor of HF with a mol concentration of about 40% to about 60% and H₂SO₄ with a mol concentration of about 40% to about 60% or a mixed liquor of HNO₃ with a mol concentration of about 65% to about 85% and HCl with a mol concentration of about 15% to about 35% may be selected as the chemical corrodent.

When the surface of the packaging region of a substrate is roughened via a chemical corrodent, referring to FIG. 9, after roughening and before coating a sealant on the packaging region of the substrate, the chemical corrodent needs to be removed. Specifically, the substrate may be cleaned by washing with water to remove the chemical corrodent. Moreover, heat treatment is performed at a temperature of about 80° C. to about 100° C. for about 10 min to about 30 min so as to volatilize the chemical corrosive liquor and the distilled water. For example, when the surfaces of the packaging regions of the first substrate and the second substrate are both roughened by chemical corrosion, the first substrate and the second substrate will be cleaned by distilled water respectively, and heat treatment will be performed at a temperature of about 80° C. to about 100° C. for about 10 min to about 30 min so as to volatilize the chemical corrosive liquor and the distilled water.

A packaging method of the invention will be introduced below by taking the packaging process of an OLED display panel as an example.

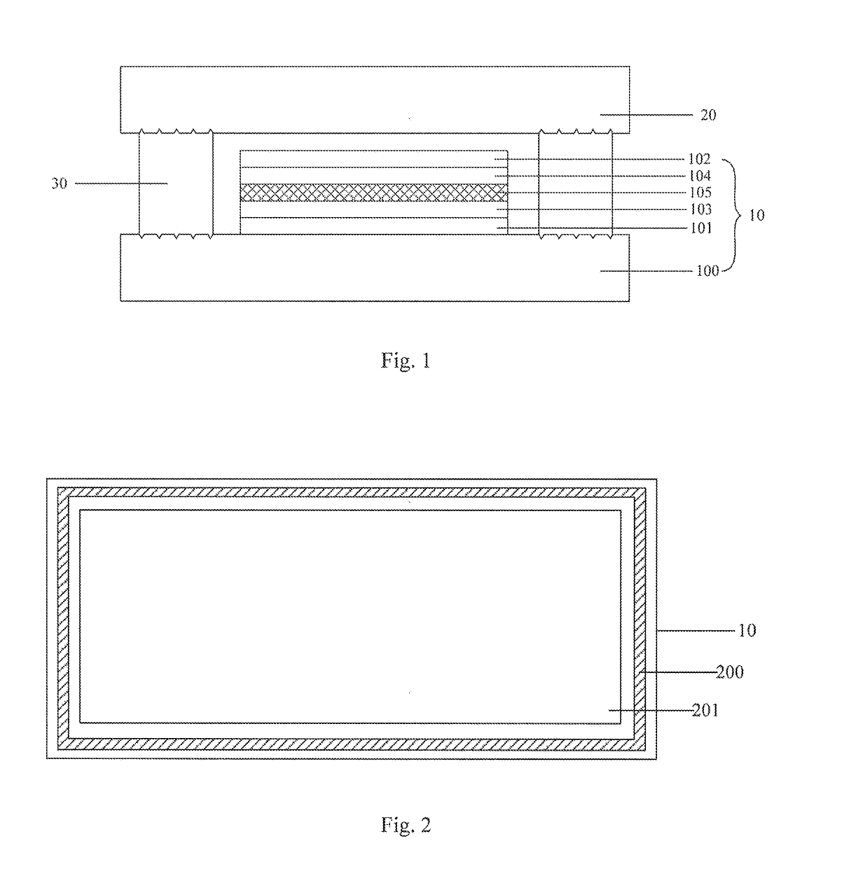

In conjunction with FIG. 1 and FIG. 2, the OLED display panel includes a first substrate 10 and a second substrate 20, the backing substrate 100 (which is a transparent substrate such as a quartz substrate, a glass substrate or an organic resin substrate, etc.) of the first substrate 10 includes a display region 201 and a non-display region located on the periphery of the display region 201, the display region 201 is formed with an OLED, and the non-display region includes a first packaging region 200. The second substrate 20 includes a second packaging region (not shown), the position of second packaging region corresponds to that of the first packaging region 200 and is opposite to that of the first packaging region 200 when they are oppositely arranged to form a cell.

Exemplarily, the packaging process of the OLED display panel includes:

Step S1: At normal temperature, the surface of the first packaging region 200 of the backing substrate 100 of the first substrate 10 (the opposite surface when oppositely arranged with the second packaging region of the second substrate to form a cell) is subjected to acidic corrosion to form a non-smooth surface, as shown in FIG. 4, Moreover, the surface of the second packaging region of the second substrate 20 (the opposite surface when oppositely arranged with the first packaging region 200 to form a cell) is subjected to acidic corrosion to form a non-smooth surface, as shown in FIG. 5. A mixed liquor of H₂O₂ with a mol concentration of about 20% to about 40% and H₂SO₄ with a mol concentration of about 60% to about 80%, a mixed liquor of HF with a mol concentration of about 40% to about 60% and H₂SO₄ with a mol concentration of about 40% to about 60% or a mixed liquor of HNO₃ with a mol concentration of about 65% to about 85% and HCl with a mol concentration of about 1.5% to about 35% may be selected as the acidic corrosive liquor. The acidic corrosive liquor may be coated on the backing substrate 100 via a spray coating process, wherein the precision of the spray coating process may reach ±20 μm, and the corrosion width may be controlled by the spray coating amount of a spray head.

Step S2: The first substrate 10 and the second substrate 20, which have been subjected to acidic corrosion as in Step S1, are cleaned by distilled water, and heat treatment is performed at a temperature of about 80° C. to about 100° C. for about 10 min to about 30 min so as to clean and volatilize the residual corrosive liquor and distilled water.

Step S3: After removing the acidic corrosive liquor as in Step S2, the backing substrate 100 of the first substrate 10 is loaded to a vacuum evaporation equipment, and each layer of an organic light-emitting diode is evaporated on the display region 201 in turn, which includes a metal anode 101, an organic luminescent layer 105 and a metal cathode 102, etc. The metal anode 102 is a transparent conducting layer, for example, ITO and IZO, and the metal cathode 101 is a reflecting layer, for example, an magnesium-silver alloy, a lithium-aluminium alloy, and aluminium, etc., as shown in FIG. 4. The organic light-emitting diode may further include other structures such as a hole transport layer 103 and an electron transport layer 104, etc.

Step S4: After forming an organic light-emitting diode on the backing substrate 100 of the first substrate 10, a liquid sealant (glass cement) 30 is coated on the second packaging region of the second substrate 20, as shown in FIG. 5, and then the sealant is dried. However, a sealant may also be coated on the first packaging region of the first substrate, or a sealant may be coated on both the first packaging region of the first substrate and the second packaging region of the second substrate.

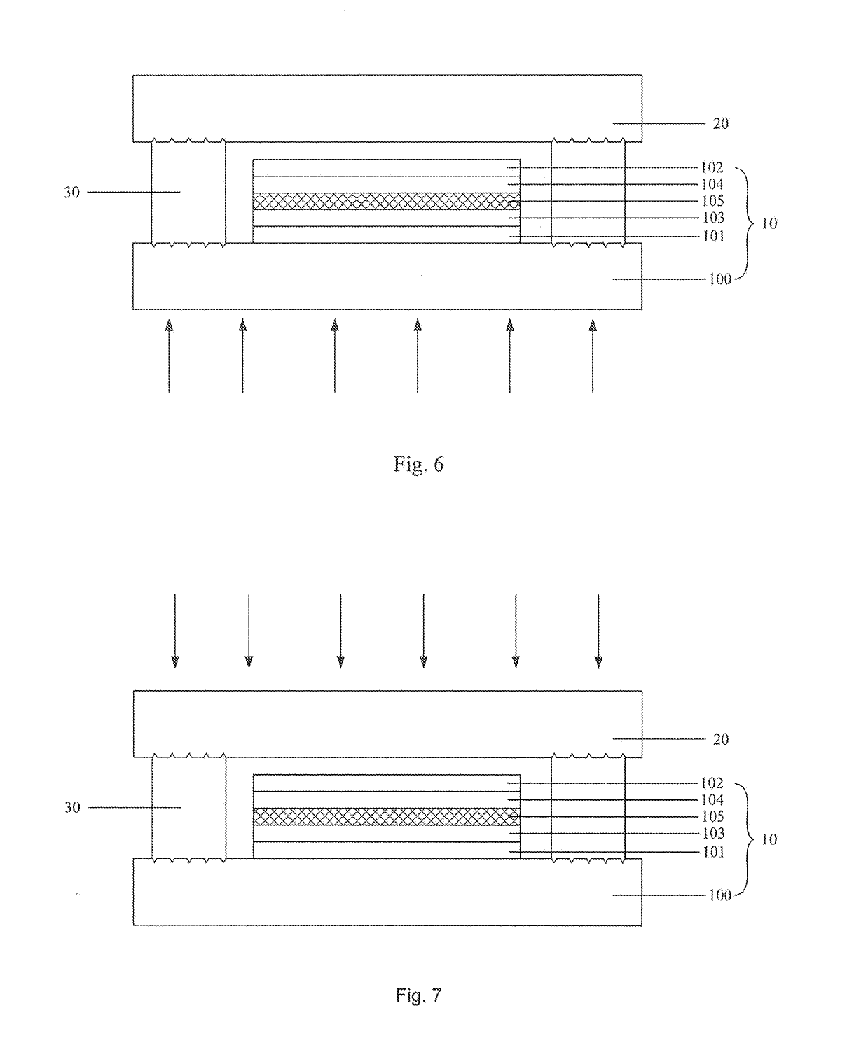

Step S5: The second substrate 20 coated with the glass cement 30 and the backing substrate 100 treated as in Step S3 are oppositely arranged to form a cell, and then the first substrate 10 and the second substrate 20 that have been oppositely arranged to form a cell are irradiated by a laser from above, as shown in FIG. 6; or the first substrate 10 and the second substrate 20 that have been oppositely arranged to form a cell are irradiated by a laser from below to fuse the glass cement 30, as shown in FIG. 7.

Step S6: The first substrate 10 and the second substrate 20 are pressed with an enough force to extrude the air, and it should be noted that no glass cement 30 is extruded, and then the first substrate 10 and the second substrate 20 that are spliced are placed at room temperature to wait for the glass cement 30 to cure.

Up to this point, the packaging of the OLED display panel is completed.

After the OLED display panel is packaged in the above steps, since the first substrate 10 and the second substrate 20 both have a non-smooth surface on the inner side thereof, the glass cement 30 is cured on the two non-smooth surfaces, and the first substrate 10 and the second substrate 20 are oppositely package to form a cell. This guarantees a good sealability of the OLED display panel, the bottleneck of the lifetime of the OLED display apparatus is solved, and the service life of the OLED display apparatus is prolonged.

The display panel may also be a liquid crystal display panel, and the packaging process thereof may be similar to that of the above OLED display panel, except that in the Step S3, structures such as a thin-film transistor, a pixel electrode, a common electrode and a color filter, etc., are formed on the first substrate and the second substrate, and these structures and the preparation methods thereof and the method for forming the liquid crystal layer may employ those known by one skilled in the art, thus no further description will be given again here. Additionally, the difference between the packaging process of the liquid crystal display panel and the packaging process of the above OLED display panel also lies in that the sealant used for packaging the liquid crystal display panel is usually a seal agent (an ultraviolet curable glue), thus in the above Step S4, a seal agent may be coated on the first packaging region of the first substrate, or a seal agent may be coated on the second packaging region of the second substrate, or a seal agent may be coated on both the first packaging region of the first substrate and the second packaging region of the second substrate, and in the above Step S5, ultraviolet light is irradiated on the first substrate and the second substrate, which have been oppositely arranged to form a cell, to cure the seal agent. For the same parts, no further description will be given again here.

In the technical solutions of the invention, by roughening the surface of at least one packaging region of two substrates that are oppositely arranged to form a cell and forming a non-smooth surface, the adhesivity between the sealant formed in the packaging region and the substrate is enhanced, the performance of blocking water vapor and oxygen is improved greatly, and it guarantees that the display panel has a good sealability, thereby the lifetime of the display apparatus will be prolonged.

The above description only shows some exemplary embodiments of the invention. It should be pointed that, for one of ordinary skills in the art, various improvements and modifications may also be made without departing from the technical principles of the invention, and these improvements and modifications should also be regarded as the protection scope of the invention.

1. A method for packaging a display panel, wherein the display panel comprises a first substrate and a second substrate, the first substrate comprises a first packaging region, the second substrate comprises a second packaging region, and a position of the first packaging region corresponds to that of the second packaging region, and the method comprises:
step A: roughening a surface of at least one of the first packaging region and the second packaging region, and forming a non-smooth surface;
step B: coating a sealant on the surface of the first packaging region and/or the second packaging region that is treated in step A;
step C: oppositely arranging the first substrate and second substrate, which are treated in step B, to form a cell; and
step D: curing the sealant.

2. The method according to claim 1, wherein in step A, the surface of the at least one of the first packaging region and the second packaging region is roughened by a chemical corrodent.

3. The method according to claim 2, wherein the chemical corrodent is a mixed liquor of H₂O₂ with a mol concentration of about 20% to about 40% and H₂SO₄ with a mol concentration of about 60% to about 80%, a mixed liquor of HF with a mot concentration of about 40% to about 60% and H₂SO₄ with a mol concentration of about 40% to about 60%, or a mixed liquor of HNO₃ with a mol concentration of about 65% to about 85% and HCl with a mol concentration of about 15% to about 35%.

4. The method according to claim 2, wherein the chemical corrodent is coated on the surface of the at least one of the first packaging region and the second packaging region via a spray coating.

5. The method according to claim 4, wherein the precision of the spray coating is about 20 μm.

6. The method according to claim 1, wherein the non-smooth surface has a uniform and continuous geometric shape.

7. The method according to claim 2, wherein after step A and before step B, the method further comprises:
step E: removing the chemical corrodent.

8. The method according to claim 7, wherein the chemical corrodent is removed by washing with water.

9. The method according to claim 7, wherein after removing the chemical corrodent, the method further comprises:
performing heat treatment at a temperature of about 80° C. to about 100° C.

10. The method according to claim 9, wherein the duration of the heat treatment is from about 20 min to about 30 min.

11. The method according to claim 1, wherein:
the sealant is glass cement, and the step of curing the sealant comprises:
irradiating the glass cement by a laser to fuse and then cure the glass cement.

12. The method according to claim 1, wherein:
the sealant is a seal agent, and the step of curing the sealant comprises:
irradiating the seal agent by ultraviolet light to curing the seal agent.

13. A method for manufacturing a display panel, wherein the display panel comprises a first substrate and a second substrate, the first substrate comprises a first packaging region, the second substrate comprises a second packaging region, and a position of the first packaging region corresponds to that of the second packaging region, and the method comprises: packaging the display panel by the method according to claim 1.

14. A display panel, comprising:
a first substrate and a second substrate, wherein the first substrate comprises a first packaging region, the second substrate comprises a second packaging region, and a position of the first packaging region corresponds to that of the second packaging region; and
a sealant cured between the first substrate and the second substrate;
wherein a surface of at least one of the first packaging region and the second packaging region is a non-smooth surface, and the sealant is cured on the non-smooth surface.

15. The display panel according to claim 14, wherein the sealant is glass cement or a seal agent.

16. The display panel according to claim 14, wherein the display panel is an organic light-emitting diode (OLED) display panel or a liquid crystal display panel.

17. A display device, comprising the display panel according to claim 14.

18. The method according to claim 3, wherein the chemical corrodent is coated on the surface of the at least one of the first packaging region and the second packaging region via a spray coating.

19. The method according to claim 7, wherein after removing the chemical corrodent, the method further comprises:
performing heat treatment at a temperature of about 80° C. to about 100° C.

20. The display panel according to claim 15, wherein the display panel is an organic light-emitting diode (OLED) display panel or a liquid crystal display panel.
